(19) United States
(12) Patent Application Publication
(10) Pub. No.: US 2026/0059783 A1
(43) Pub. Date: Feb. 26, 2026

(54) Diamond-Based High-Electron-Mobility Modulation-Doped Field-Effect Transistors

(71) Applicant: Wisconsin Alumni Research Foundation, Madison, WI (US)

(72) Inventor: Zhenqiang MA, Middleton, WI (US)

(21) Appl. No.: 18/771,826

(22) Filed: Jul. 12, 2024

(51) Int. Cl. H10D 30/47; H10D 30/01; H10D 62/60; H10D 62/82

(52) U.S. Cl. CPC H10D 30/475; H10D 62/60; H10D 62/82; H10D 30/015

(57) ABSTRACT

N-channel modulation-doped field-effect transistors (N-MODFETs) in which a two-dimensional electron gas (2DEG) channel is formed in intrinsic diamond are provided. The n-MODFETs can be made using bandgap engineering and a transfer and grafting process to couple intrinsic diamond, which has a very high electron mobility, with a highly n-type doped aluminum gallium nitride (AlGaN) alloy as an electron donor material to realize a high-cutoff frequency (f_{T}) MODFET for radiofrequency (RF) electronics applications.

### REFERENCE TO GOVERNMENT RIGHTS

This invention was made with government support under N00014-18-1-2032 awarded by the NAVY/ONR. The government has certain rights in the invention.

### BACKGROUND

Single crystal diamond has excellent electronic properties, including high charge carrier mobility (μₑ/μₕ: 7,300 cm²/V·s/5,300 cm²/V·s), high saturation velocity (vₛ) (c/h: 1.9×10⁷ cm/s/1.4×10⁷ cm/s), high thermal conductivity (2,290 W/K·m), a large bandgap (5.5 eV), and a very high electrical breakdown field (E_{c}) (13 MV/cm). (Tsao, et al., Adv. Electron. Mater. 2018, 4, 1600501.) In addition, diamond has a tunable electron affinity value ranging from −1.7 eV to more than 2 eV, providing the flexibility for engineering the band structure and band alignment with other materials. (Maier, et al., PHYSICAL REVIEW B, VOLUME 64, 16541 (2001).) The calculated Johnson's figure of merit (JFoM) of an electron-channel diamond field-effect transistor (FET) and that of a hole-channel diamond FET are much higher than today's highest JFoM for GaN HEMT (20 nm gate length): 4.5 TH_{z}·V. (Tang et al., IEEE ELECTRON DEVICE LETTERS, 36(6), 549-551 (2015).) As a result, diamond is considered a promising semiconductor material for radiofrequency (RF) power electronic devices and high-power electronic devices (e.g., rectifiers and power conditioning devices). However, diamond has inherent drawbacks that prevent exploitation of its outstanding electronic properties. The major drawback is the lack of effective n-type dopant. When using the typical Column V elements, such as nitrogen (N) and phosphorous (P), as n-type donors, the donor energy level (Ea) is about 1.7 eV and 0.6 eV, respectively, below the conduction band edge of the diamond band structure. (Stenger, et al., J. Appl. Phys. 114, 073711 (2013).) Therefore, these deep level donors are very difficult to electrically activate. This drawback prevents the development of diamond-based pn junction, bipolar junction transistors, and electron-channel FETs. Therefore, prevalent diamond device research has been mainly focused on hole-channel FETs and boron (B) doped p-type Schottky diodes. Because of the low hole mobility (50-200 cm²/V·s versus 5,300 cm²/V·s) caused by impurity (mainly B dopants) in the FETs, the highest cut-off frequency of diamond FETs is only 70 GHz with a gate length of 100 nm. (Yu, et al., “IEEE ELECTRON DEVICE LETTERS, 36(6), 549-551 (2015),” IEEE ELECTRON DEVICE LETTERS, 39(9), 1373-1375 (2018).) Regardless of the extremely high electron mobility in diamond, electron channel diamond FETs have not been realized due to the inability to form an electron device channel. Therefore, present approaches to implementing diamond FETs do not fully utilize the electronic potential of diamond.

### SUMMARY

Semiconductor heterostructures, modulation-doped field-effect transistors

incorporating the semiconductor heterostructures, and methods of operating the modulation-doped field-effect transistors are provided.

One embodiment of a semiconductor heterostructure includes: an electron donor layer comprising n-type doped AlGaN; a barrier layer comprising intrinsic AlN below the electron donor layer; a current tunneling layer below the barrier layer, the current tunneling layer comprising an inorganic material having a bandgap that is wider than the bandgap of the n-type doped AlGaN and wider than the bandgap of intrinsic diamond; and a layer of intrinsic diamond below the current tunneling layer, wherein the current tunneling layer forms a junction between the barrier layer and the layer of intrinsic diamond and a two-dimensional electron gas is formed in the layer of intrinsic diamond below the junction.

One embodiment of a modulation-doped field-effect transistor includes: a semiconductor heterostructure of a type described herein; a source on the semiconductor heterostructure; a drain on the semiconductor heterostructure; a gate; and a Schottky contact layer separating the source, the drain, and the gate from the electron donor layer, the Schottky contact layer comprising a semiconductor that forms a Schottky contact with the gate, wherein the two-dimensional electron gas forms a conductive channel between the source and the drain and the gate is configured to modulate the flow of electrons in the conductive channel upon the application of a gate bias voltage.

One embodiment of a method of operating a modulation-doped field-effect transistor of a type described herein includes the steps of: creating a potential drop between the source and the drain, thereby inducing a current to flow through the 2DEG; and modulating the flow of the current in the 2DEG by applying a negative bias voltage to the gate.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 shows a schematic of one example of a diamond n-MODFET.

FIG. 2, panels (a1)-(i), show an illustration of a fabrication process for a diamond n-MODFET. FIG. 2, panels (a1)-(c1), show nitride layers growth. FIG. 2, panel (d1), shows release of the grown nitride layers. FIG. 2, panels (a2)-(b2), show epitaxial growth of an intrinsic diamond channel layer on a diamond substrate, where the diamond is surface treated to adjust its electron affinity value. FIG. 2, panel (c2), shows the deposition of an Al₂O₃ current tunneling layer using Atomic Layer Deposition (ALD). FIG. 2, panel (e), shows the transfer and grafting the nitride layers to the intrinsic diamond. FIG. 2, panels (f)-(h), show n-MODFET fabrication. FIG. 2, panel (i), shows surface passivation.

FIG. 3A shows a band diagram of each of the constituent materials in the n-MODFET structure, showing a conduction band alignment suitable for n-MODFET device operation. FIG. 3B shows a simulated band diagram of the diamond n-MODFET under equilibrium (zero bias for gate and drain). A triangular quantum well is formed at the AlN/diamond interface. FIG. 3C shows a simulated electron concentration profile of the n-MODFET. A two-dimensional electron gas (2DEG) is formed inside diamond near the diamond/AlN junction.

FIG. 4A shows simulated transfer characteristics of the diamond n-MODFET shown in FIG. 1. FIG. 4B shows simulated output characteristics of the diamond n-MODFET shown in FIG. 1. FIG. 4C shows simulated current gain as a function of frequency under bias of V_{G}=0 V and V_{DS=}20 V, indicating a f_{T}of 300 GHz.

FIG. 5A shows a schematic of a downscaled diamond n-MODFET with vertical and lateral device dimensions identical to that of a state-of-the-art GaN HEMT. FIG. 5B shows simulated current gain as a function of frequency of the device of FIG. 5A under bias of V_{G}=0 V and V_{DS=}2 V, indicating a f_{T} of 1 THz.

### DETAILED DESCRIPTION

N-channel MODFETs (n-MODFETs) in which a 2DEG channel layer is formed in an intrinsic diamond layer are provided. The n-MODFETs can be made using bandgap engineering and a transfer and grafting process to couple intrinsic diamond, which has a very high electron mobility, with a highly doped aluminum gallium nitride (AlGaN) alloy as an electron donor material to realize high-cutoff frequency (f_{T}) n-MODFETs for RF electronics applications.

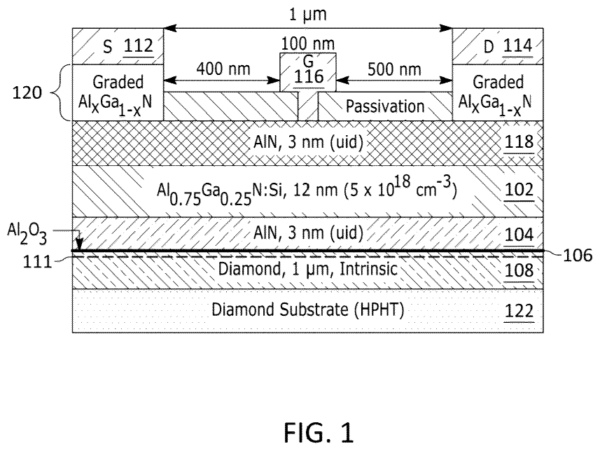

The structure of an example of a diamond-based n-MODFET is shown schematically in FIG. 1. The MODFET is based on a heterostructure that includes a layer of n-type doped aluminum gallium nitride (n-AlGaN) 102 as an electron donor and a layer of intrinsic diamond 108 as an electrically conductive channel material. In the n-MODFET, the intrinsic diamond layer is undoped to avoid impurity scattering in order to achieve high charge carrier mobility in the conductive channel. For the purposes of this disclosure, an intrinsic semiconductor is a semiconductor material that has not been extrinsically doped; intrinsic semiconductors are also referred to as undoped or unintentionally doped (uid) semiconductors.

It is advantageous to use Al₁₋ₓGaₓN alloys with x of at least 0.65 in order to achieve high dopant concentrations in the electron donor layer. Such high aluminum content alloys can be doped to concentrations of 1×10¹⁸ cm⁻³ or greater, 5×10¹⁸ cm⁻³ or greater, or even 1×10¹ cm³ or greater. By way of illustration only, Al₁₋ₓGaₓN alloys with 0.65≤x≤0.85 can be used. Dopant concentrations in this range are sufficient to supply electrons with a high sheet charge concentration in the conductive channel. Silicon is typically used as the n-type dopant for the n-AlGaN. However, other n-type dopants, such as germanium, can be used.

The Al₁₋ₓGaₓN and the diamond are separated by a barrier layer of intrinsic aluminum nitride (AlN) 104, and the intrinsic AlN and the adjacent intrinsic diamond, which are lattice mismatched, are bonded together by an inorganic current tunneling layer 106 that forms a passivating junction between the AlN and the diamond.

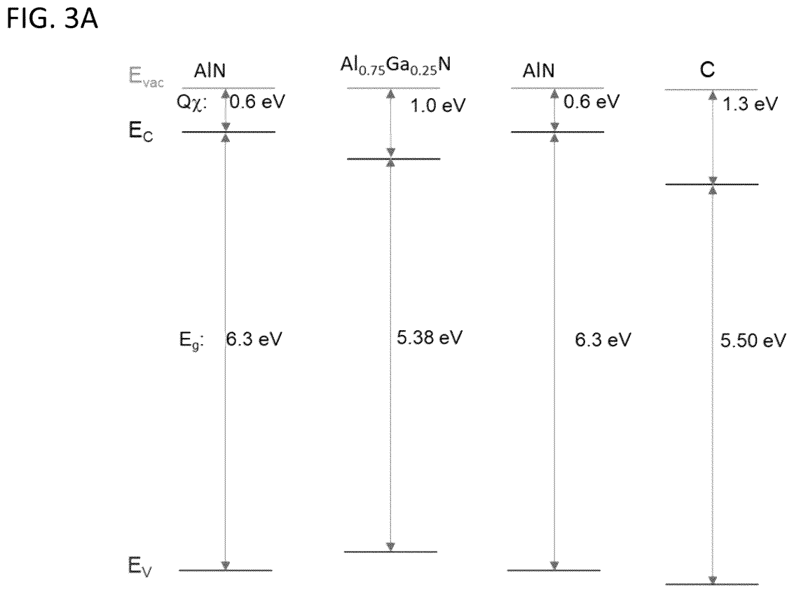

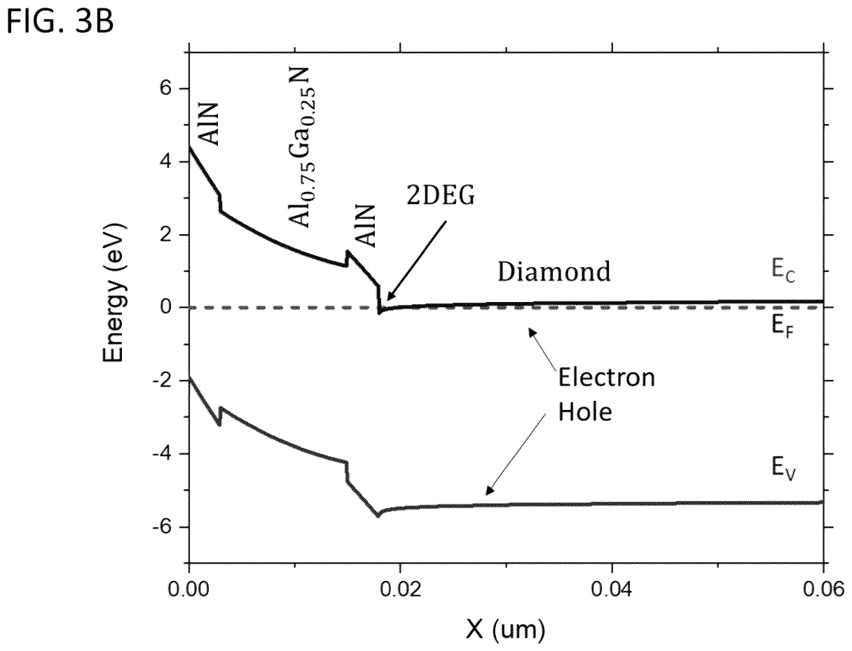

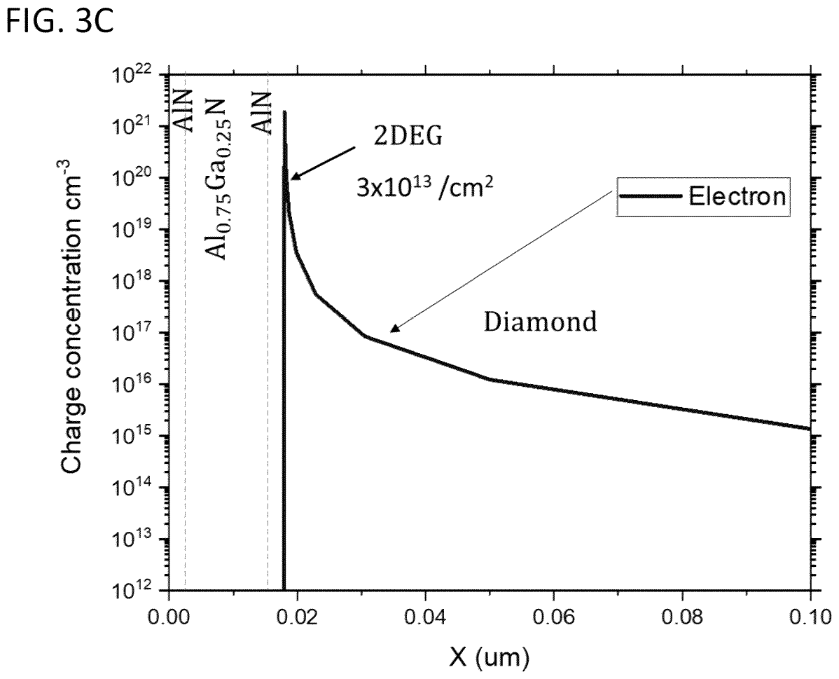

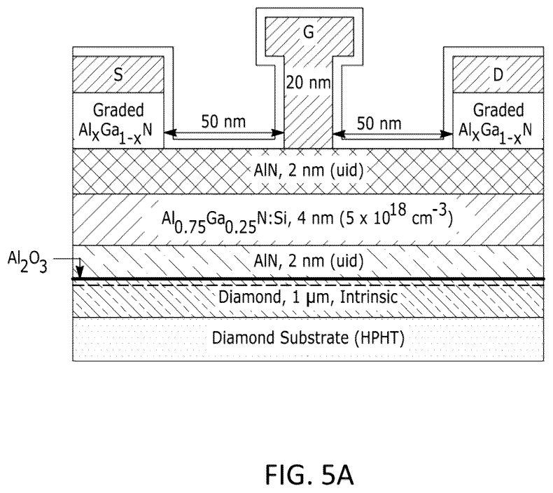

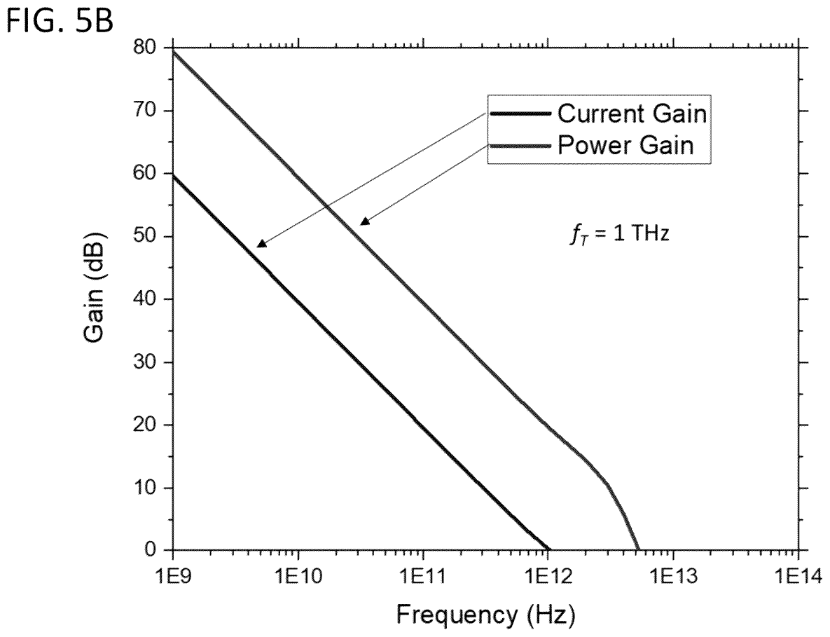

The electron affinity of diamond can be tuned using surface treatments, such as plasma treatments. (See, for example, Maier, F., J. Ristein, and L. Ley. “Electron affinity of plasma-hydrogenated and chemically oxidized diamond (100) surfaces.” Physical Review B 64.16 (2001): 165411.) This tunability is advantageous for the purposes of the present n-MODFETs because, by utilizing intrinsic diamond having an electron affinity that is higher than that of intrinsic AlN and n-AlGaN, a semiconductor heterostructure having a proper band alignment for n-MODFET operation can be fabricated. Intrinsic diamond having an electron affinity greater than about 1 eV, including intrinsic diamond having an electron affinity of about 1.3 eV is suitable for this purpose. FIGS. 3A and 3B show that the bandgaps and electron affinities of the intrinsic diamond, the intrinsic AlN, and the n-AlGaN produce a conduction band alignment in the semiconductor heterostructure that is extremely well-suited for an n-MODFET. As shown in FIG. 3A, both n-AlGaN and intrinsic AlN have higher bandgaps than the intrinsic diamond, while the intrinsic diamond has a higher electron affinity than the n-AlGaA and the intrinsic AlN. The resulting band alignment for the heterostructure is shown in FIG. 3B, where the formation of a triangular quantum well that provides a 2DEG 111 (represented by dashed line in FIG. 1 and FIG. 5A) in the diamond can clearly be seen.

Since the electron affinity of the intrinsic diamond is higher than that of the n-AlGaN, electrons are transferred from the n-AlGaN to the intrinsic diamond where they become confined in the 2DEG 111 that forms just below the current tunneling layer/intrinsic diamond interface. The transferred electrons in the diamond layer 108 are, therefore, spatially separated from their donor atoms in the electron donor layer 102 of the MODFET, which reduces Coulomb scattering and leads to exceptional mobilities for the conducting electrons in the 2DEG 111. Moreover, the Coulomb interaction between the electrons in 2DEG 111 and the ionized donor atoms in electron donor layer 102 can be reduced by the AlN barrier layer 104, further improving electron mobility.

The MODFET further includes a source 112, a drain 114, and a gate 116, which may be formed from metals, such as gold. When the MODFET is in operation, current flowing between source 112 and drain 114 via the 2DEG channel 111 is modulated by gate 116 via the application of a gate bias voltage. When a positive voltage is applied to the drain, current flows along the 2DEG due to the potential drop between source and drain. The magnitude of the current between the source and the drain is controlled by the space charge, which is controlled by the voltage applied to the gate. Negatively biasing the gate of the MODFET begins to deplete the 2DEG beneath the gate until a pinch-off voltage is reached and the MODFET is switched to an off-state.

The contact between gate 116 and the semiconductor heterostructure is a Schottky contact in order to prevent large currents from flowing through the gate and to limit tunneling to the 2DEG channel. To provide a Schottky contact with good rectifying properties, a Schottky contact layer 118 comprising a semiconductor that forms a large Schottky barrier may be inserted between gate 116 and electron donor layer 102. Intrinsic AlN is an example of a material that can be used as Schottky contact layer 118.

Unlike gate 116, source 112 and drain 114 should form ohmic contacts with the semiconductor heterostructure. In order to provide a good ohmic contact with source 112 and drain 114, a capping layer 120 comprising a semiconductor that forms a low resistance ohmic contact with the source and drain can be inserted between source and drain (112 and 114) and the Schottky contact layer 118. Compositionally graded AlGaN is one example of a material that can be used to form an ohmic contact, including n-AlGaN that is compositionally graded down to n-GaN.

FIG. 1 provides illustrative dimensions for the various material layers in the MODFET and a possible dopant concentration for the n-AlGaN. These are provided for guidance only. Other dimensions and doping levels can be used. However, as the MODFETs are typically intended for use in micro-electronics applications, the lateral (width) and height dimensions for the MODFETs may be designed to provide a device with lateral dimensions of 5 μm or smaller and/or a height dimension of 5 μm or smaller; these dimension ranges may exclude a substrate 122, if one is present.

The current tunneling layer is formed of an inorganic material having a bandgap that is wider that the bandgaps of the intrinsic diamond and the AlN of the barrier layer. Current tunneling layers are characterized in that they are made from an appropriate material and are sufficiently thin that they are able to act as tunneling layers for electrons and/or holes. That is, unlike a typical dielectric medium, they allow both electrons and holes to pass through, from a first layer to a second layer of semiconductor material, via quantum tunneling. Thus, because metals would block the passage of holes, metals are not suitable materials for a current tunneling layer. However, a wide range of non-metal inorganic materials can meet these criteria. The inorganic material of the current tunneling layer may be a material that would act as a dielectric in its bulk form but is sufficiently thin that it no longer acts as an electrical insulator. This intervening layer of inorganic material passivates the surfaces of the material layers with which it is in contact, such that dangling bonds and interface states are minimized or substantially reduced. This property is useful because, when directly bonding two non-lattice matched single-crystalline materials, the chemical bonds formed between the two materials can create a large number of interface states. These interface states prevent the two materials from forming an ideal junction. However, when the inorganic material is inserted, the two materials are physically separated. If the layer is sufficiently thin and has the capability to chemically passivate the materials, the number of interface states can be reduced to levels such that both electrons and holes can efficiently tunnel through the layer. The inorganic layer also provides a sort of ‘glue’ between the layers and can prevent the interdiffusion of the semiconductor materials between the layers. This avoids the formation of an unwanted, intervening, cross-contaminated semiconductor interface layer. In addition, the current tunneling layer can stabilize the diamond surface after surface treatment.

In some embodiments of the MODFETs, the inorganic material of the current tunneling layer is an oxide. In such embodiments, the oxide can comprise, consist of, or consist essentially of, a metal oxide, an oxide of a semiconductor element, and/or an oxide of a metalloid element. Examples of oxides that may be used in metal oxide current tunneling layers include, but are not limited to, those that can be deposited via atomic layer deposition (ALD). Examples of such oxides include aluminum oxide (Al₂O₃), titanium oxide (TiO₂), hafnium oxide (HfO₂), and tantalum oxide (Ta₂O₅). The current tunneling layer is actively deposited, rather than passively formed. Thus, in embodiments of the current tunneling layers that comprise oxides, the inorganic oxide is not merely a native oxide of diamond or the AlN. (As used herein, the term native oxide refers to an oxide that would be monolithically formed on the semiconductor material as the result of the natural oxidation of the material in an oxygen-containing environment.)

In other embodiments, the inorganic material of the current tunneling layer is a nitride. In such embodiments, the nitride can comprise, consist of, or consist essentially of, a metal nitride, a nitride of a semiconductor element, and/or a nitride of a metalloid element. Examples of nitrides that may be used in nitride current tunneling layers include, but are not limited to, those that can be deposited via ALD. Examples of such nitrides include silicon nitride and titanium nitride. In some embodiments, the metal, semiconductor, or metalloid elements present in the nitride are different from any metal, semiconductor, or metalloid elements in the semiconductor layers with which they are in contact and between which they are disposed.

In some embodiments, the current tunneling layer comprises two or more sub-layers, each of which comprises an inorganic current tunneling material, provided, however, that the total combined thickness of the sub-layers is still low enough to allow for the tunneling of electrons and holes through the layer. For example, in a current tunneling layer comprising multiple sub-layers of inorganic oxides, the inorganic oxides can be selected such that one oxide passivates one of the two neighboring semiconductor materials, while another oxide passivates the other of the two neighboring semiconductor materials.

The thickness of the current tunneling layer typically need only be on the order of the root mean square (rms) roughness of the surfaces of the diamond and AlN layers which it binds. By way of illustration, in some embodiments, the current tunneling layer has a thickness in the range from about 0.5 nm to about 10 nm. This includes embodiments in which it has a thickness in the range from about 0.5 nm to about 5 nm or from about 0.5 nm to about 3 nm. Since the thickness of the current tunneling layer may not be uniform on an atomic scale, the thickness of the layer corresponds to the average thickness of the layer across the bonding interfaces of the heterostructure.

The MODFETs can be fabricated using a thin film transfer and grafting process that does not require epitaxial growth or lattice matching between the nitride semiconductors and the diamond. Because the transfer and grafting process does not rely upon epitaxial growth at a heterojunction between the intrinsic AlN and the intrinsic diamond, the non-epitaxial interfaces provided by the current tunneling layer are free of lattice mismatch-induced strains or stresses and lattice mismatch-induced misfit dislocations.

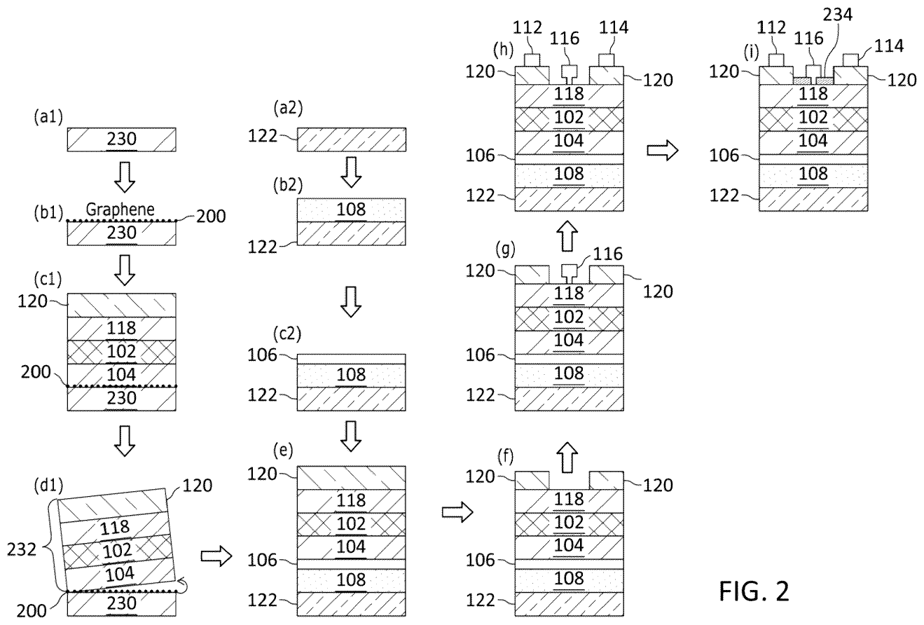

The transfer and grafting process allows the intrinsic diamond channel layer to be fabricated separately from the barrier and electron donor layers and subsequently bonded to the barrier layer via the current tunneling layer to form a stacked semiconductor heterostructure. One method of making an n-MODFET is shown schematically in FIG. 2, panels (a1)-(i). Panels (a1)-(d1) in FIG. 2 illustrate one method for forming a heterostructure that includes an AlN barrier layer, an n-AlGaN electron donor layer, and an AlN Schottky contact layer. In the method of FIG. 2, panels (a1)-(i), the AlN 104 barrier layer and then the n-AlGaN electron donor layer 102 can be grown using graphene interfaced epitaxy and then released as a whole, by peeling off from the graphene interface. (P. Wang, et al., Applied Physics Letters, 116, 171905 (2020).) Graphene interfaced epitaxy begins with an AlN substrate 230 (FIG. 2, panel (a1)). A layer of graphene 200 is grown or deposited on the AlN growth substrate 230 (FIG. 2, panel (b1)) and a high-quality, single-crystalline layer of AlN 104 can be grown epitaxially through the graphene (FIG. 2, panel (c1)), with the underlying AlN growth substrate 230 governing the initial AlN nucleation. High-quality, single-crystalline n-AlGaN electron donor 102, AlN Schottky contact 118, and capping 120 layers can then be grown sequentially via epitaxy on AlN Schottky contact 118 (FIG. 2, panel (c1)). The stacked AlN/n-AlGaN/AlN/Cap heterostructure 232 can then be released from the underlying growth substrate 230 using graphene interlayer 200 as a natural break point (FIG. 2, panel (d1)).

A thicker n-AlGaN layer may provide a higher electron concentration in the 2DEG channel. However, a thicker n-AlGaN layer, as well as a thicker barrier layer, will increase the tunneling distance between the source and drain and the 2DEG. Therefore, the various layer thicknesses can be selected based on a balancing of these considerations and the demands of the MODFET application. Generally, AlN layer thicknesses in the range from 2 nm to 5 nm and an n-AlGaN layer thickness in the range from 10 nm to 20 nm are suitable. However, thicknesses outside of these ranges can be used.

In a separate material growth process (FIG. 2, panels (a2) through (c2)), a high-quality, single-crystalline layer of intrinsic diamond 108 can be grown on a diamond substrate 122 (FIG. 2, panels (a2) and (b2)). This can be accomplished by High-Pressure High-Temperature (HPHT) growth or other methods. (See, for example, Khmelnitskiy, R. A. “Prospects for the synthesis of large single-crystal diamonds.” Physics-Uspekhi 58.2 (2015): 134).) A film of inorganic current tunneling material 106 is then deposited on the surface of intrinsic diamond layer 108 using, for example, ALD (FIG. 2, panel (c2)).

Released heterostructure 232 is then transferred onto current tunneling layer 106, such that the exposed surface of barrier layer 104 is bonded to the surface of intrinsic diamond layer 108 using current tunneling layer 106 as a sort of glue (FIG. 2, panel (c)). Mesa structures can be lithographically patterned into capping layer 120 to expose a portion of the surface of Schottky contact layer 118 (FIG. 2, panel (f)), and contact metallization can be used to form source 112, drain 114, and gate 116 (FIG. 2, panels (g) and (h)). Finally, a layer of surface passivating material 234 may be deposited over the exposed surfaces of the semiconductor heterostructure (FIG. 2, panel (i)).

### EXAMPLE

FIG. 3A shows the band diagram of each of the constituent materials in the n-MODFET structure. Considering the fixed electron affinity (including the band bending effects) values of AlN and Al_{0.75}Ga_{0.25}N, the electron affinity of diamond can be tuned to around 1.3 cV to form a properly aligned conduction band for n-MODFET. FIG. 3B shows the simulated band diagram of the diamond n-MODFET layer structure under equilibrium, indicating the formation of a triangular quantum well at the AlN/diamond interface. The electron concentration profile of the n-MODFET is shown in FIG. 3C. The 2DEG density reached 3×10¹³/cm² and no parasitic electron or hole channel was formed in the Al_{0.75}Ga_{0.25}N donor layer.

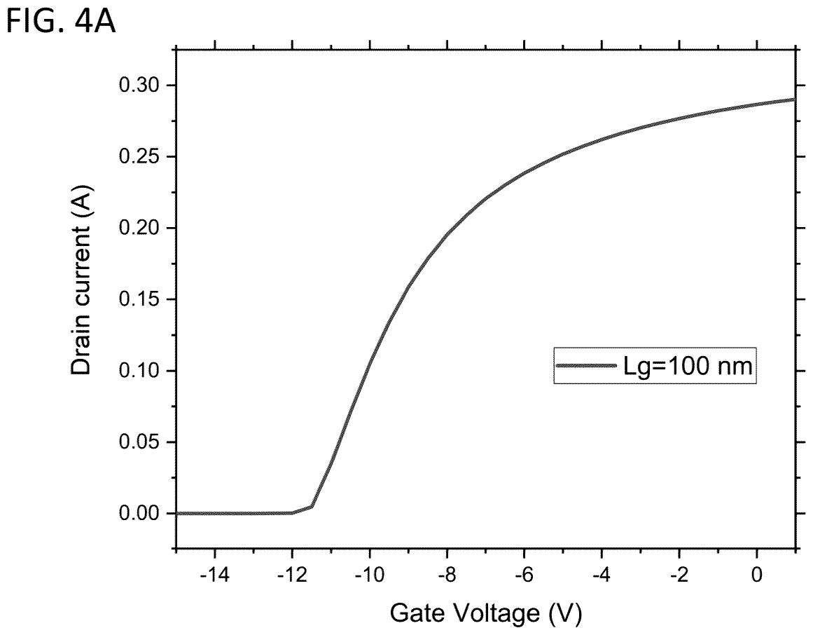

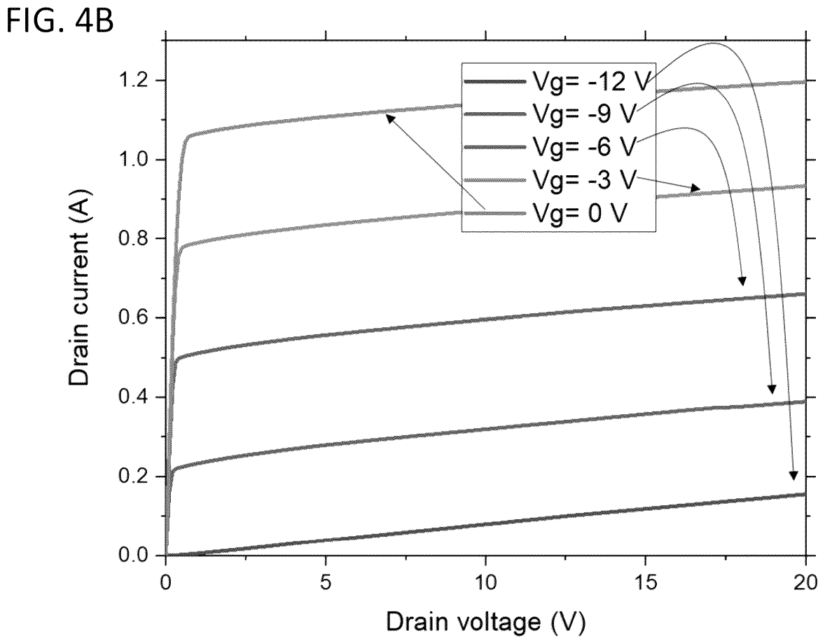

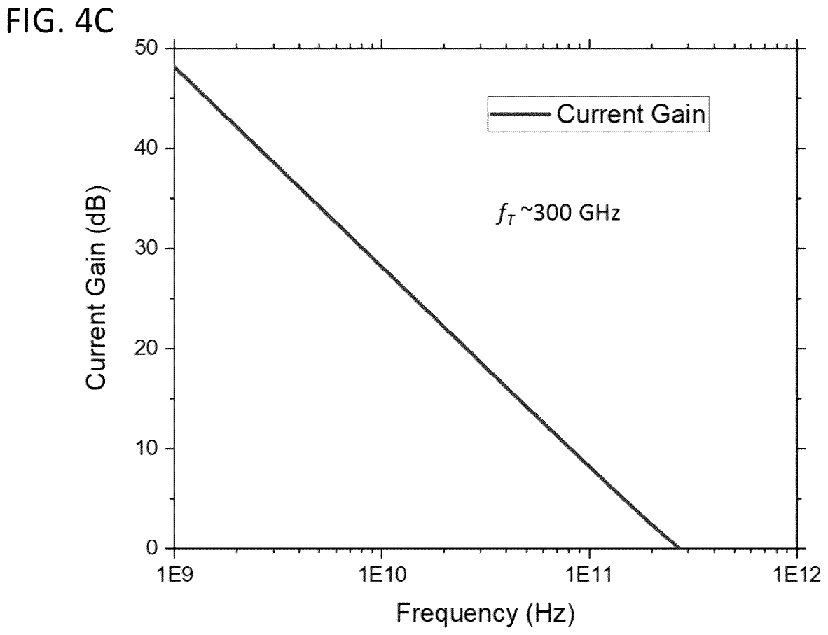

The diamond n-MODFET shown in FIG. 1 was simulated using Silvaco tools to verify the device vertical layer design and lateral geometry design, and the results are shown in FIGS. 4A-4C. FIG. 4A and FIG. 4B show the de characteristics of the diamond n-MODFET, and FIG. 4C shows the simulated current gain as a function of frequency under bias of V_{G}=0 V and V_{DS}=20 V, indicating a f_{T} of 300 GHz with a gate length (Lg) of 100 nm, gate-to-source distance (d_{gs}) of 400 nm, and a gate-to-drain distance (ded) of 500 nm.

To benchmark with the state-of-the-art GaN HEMT, a downscaled version of the diamond n-MODFET, as shown in FIG. 5A, with the lateral and vertical dimensions comparable with that the state-of-the-art GaN HEMT was also simulated. (Tang et al., 2015.) FIG. 5B shows the simulated current gain and power gain of the scaled n-MODFET, indicating a f_{T} of 1 TH_{Z}, equivalent to a JFoM of 65 THz·V, which is more than 14 times higher than that of the state-of-the-art GaN HEMT.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A semiconductor heterostructure comprising:
an electron donor layer comprising n-type doped AlGaN;
a barrier layer comprising intrinsic AlN below the electron donor layer;
a current tunneling layer below the barrier layer, the current tunneling layer comprising an inorganic material having a bandgap that is wider than a bandgap of the n-type doped AlGaN and wider than a bandgap of intrinsic diamond; and
a layer of intrinsic diamond below the current tunneling layer, wherein the current tunneling layer forms a junction between the barrier layer and the layer of intrinsic diamond and a two-dimensional electron gas is formed in the layer of intrinsic diamond below the junction.

2. The semiconductor heterostructure of claim 1, wherein the inorganic material is an inorganic metal oxide or an inorganic metal nitride.

3. The semiconductor heterostructure of claim 1, wherein the inorganic material is aluminum oxide.

4. The semiconductor heterostructure of claim 1, wherein the current tunneling layer has a thickness of 10 nm or less.

5. The semiconductor heterostructure of claim 1, wherein the n-type doped AlGaN is silicon doped Al₁₋ₓGaₓN, wherein x≤0.65, having a silicon dopant concentration of at least 1×10¹⁷ cm⁻³.

6. A modulation-doped field-effect transistor comprising:
a semiconductor heterostructure comprising:
an electron donor layer comprising n-type doped AlGaN;
a barrier layer comprising intrinsic AlN below the electron donor layer;
a current tunneling layer below the barrier layer, the current tunneling layer comprising an inorganic material having a bandgap that is wider than a bandgap of the n-type doped AlGaN and wider than a bandgap of intrinsic diamond; and
a layer of intrinsic diamond below the current tunneling layer, wherein the current tunneling layer forms a junction between the barrier layer and the layer of intrinsic diamond and a two-dimensional electron gas is formed in the layer of intrinsic diamond below the junction; and
a source on the semiconductor heterostructure;
a drain on the semiconductor heterostructure;
a gate; and
a Schottky contact layer separating the source, the drain, and the gate from the electron donor layer, the Schottky contact layer comprising a semiconductor that forms a Schottky contact with the gate, wherein the two-dimensional electron gas forms a conductive channel between the source and the drain and the gate is configured to modulate a flow of electrons in the conductive channel upon application of a gate bias voltage.

7. The modulation-doped field-effect transistor of claim 6, wherein the inorganic material is an inorganic metal oxide or an inorganic metal nitride.

8. The modulation-doped field-effect transistor of claim 6, wherein the inorganic material is aluminum oxide.

9. The modulation-doped field-effect transistor of claim 6, wherein the current tunneling layer has a thickness of 10 nm or less.

10. The modulation-doped field-effect transistor of claim 6, wherein the n-type doped AlGaN is silicon doped Al₁₋ₓGaₓN, wherein x≤0.65, having a silicon dopant concentration of at least 1×10¹⁸ cm³.

11. The modulation-doped field-effect transistor of claim 6, wherein the Schottky contact layer comprises AlN.

12. The modulation-doped field-effect transistor of claim 6, wherein the semiconductor heterostructure further comprises a capping layer between the source and the Schottky contact layer and between the drain and the Schottky contact layer, the capping layer comprising a semiconductor that forms ohmic contacts with the source and the drain.

13. The modulation-doped field-effect transistor of claim 12, wherein the Schottky contact layer comprises AlN and the capping layer comprises graded AlGaN.

14. The modulation-doped field-effect transistor of claim 13, wherein the inorganic material is aluminum oxide.

15. The modulation-doped field-effect transistor of claim 6, further comprising a voltage source configured to apply the gate bias voltage to the gate.

16. A method of operating a modulation-doped field-effect transistor comprising:
a semiconductor heterostructure comprising:
an electron donor layer comprising n-type doped AlGaN;
a barrier layer comprising intrinsic AlN below the electron donor layer;
a current tunneling layer below the barrier layer, the current tunneling layer comprising an inorganic material having a bandgap that is wider than a bandgap of the n-type doped AlGaN and wider than a bandgap of intrinsic diamond; and
a layer of intrinsic diamond below the current tunneling layer, wherein the current tunneling layer forms a junction between the barrier layer and the layer of intrinsic diamond and a two-dimensional electron gas is formed in the layer of intrinsic diamond below the junction; and
a source on the semiconductor heterostructure;
a drain on the semiconductor heterostructure;
a gate; and
a Schottky contact layer separating the source, the drain, and the gate from the electron donor layer, the Schottky contact layer comprising a semiconductor that forms a Schottky contact with the gate, wherein the two-dimensional electron gas forms a conductive channel between the source and the drain and the gate is configured to modulate a flow of electrons in the conductive channel upon application of a gate bias voltage,
the method comprising:
creating a potential drop between the source and the drain, thereby inducing a current to flow through the 2DEG; and
modulating the flow of the current in the 2DEG by applying a negative bias voltage to the gate.

17. The method of claim 16, wherein the inorganic material is an inorganic metal oxide or an inorganic metal nitride.

18. The method of claim 16, wherein the inorganic material is aluminum oxide.

19. The method of claim 16, wherein the current tunneling layer has a thickness of 10 nm or less.

20. The method of claim 16, wherein the Schottky contact layer comprises AlN.
